(19) United States
(12) Patent Application Publication
(10) Pub. No.: US 2014/0240485 A1
(43) Pub. Date: Aug. 28, 2014

(54) DEVICE FOR ASSEMBLING PHOTOELECTRIC ELEMENT ONTO SUBSTRATE

(71) Applicant: Hon Hai Precision Industry Co., Ltd., New Taipei (TW)

(72) Inventor: CHIH-CHEN LAI, New Taipei (TW)

(21) Appl. No.: 13/928,159

(22) Filed: Jun. 26, 2013

(30) Foreign Application Priority Data
Feb. 27, 2013 (TW) 102107129

(51) Int. Cl. H04N 7/18; H05K 3/30

(52) U.S. Cl. CPC H04N 7/18; H05K 3/305
USPC 348/87

(57) ABSTRACT

A device for applying conductive glue and assembling a glued photoelectric element on a substrate operates a vacuum-lift nozzle, a driver, a first camera module, a second camera module, and a third camera module. The first, second, and third camera modules take images of the photoelectric element on a supply tray, check for absence of tilt during a dipping into the conductive glue, and supervise the accurate positioning of the photoelectric element onto a substrate on an output tray.

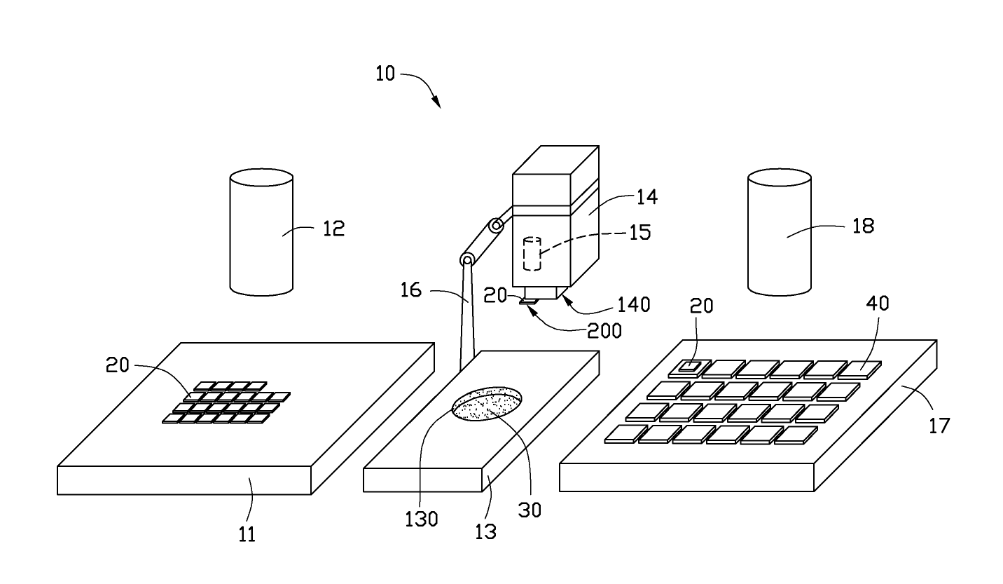

### BACKGROUND

1. Technical Field

The present disclosure relates to optical connectors and, particularly to a device for assembling a photoelectric element onto a substrate.

2. Description of Related Art

Optical connectors include a substrate and a photoelectric element positioned on the substrate. To ensure high quality, it is required that the photoelectric element is positioned precisely. However, current assembly precision of the photoelectric element onto the substrate is less than satisfactory.

Therefore, it is desirable to provide a device for assembling a photoelectric element on a substrate, which can overcome the above-mentioned problems.

### BRIEF DESCRIPTION OF THE DRAWING

Many aspects of the present disclosure can be better understood with reference to the following drawing. The components in the drawing are not necessarily drawn to scale, the emphasis instead being placed upon clearly illustrating the principles of the present disclosure.

The drawing is a schematic view of a device for assembling a photoelectric element onto a substrate, according to an embodiment.

### DETAILED DESCRIPTION

Embodiments of the present disclosure will be described with reference to the drawing.

Referring to the drawing, a device 10, according to an embodiment, is configured for assembling a photoelectric element 20 onto a substrate 40. The device 10 includes a first tray 11, a first camera module 12, a base 13, a nozzle 14, a second camera module 15, a driver 16, a second tray 17, and a third camera module 18.

The first tray 11 supports the photoelectric element 20. To increase efficiency, the first tray 11 can be configured to support a number of the photoelectric elements 20, which can be arrayed. The photoelectric element 20 can be a light emitting element such as a light emitting diode, a laser diode, or a light detecting element such as a photo diode. The photoelectric element 20 includes a bonding surface 200.

The first camera module 12 is positioned above the first tray 11 and takes images of the photoelectric element 20 on the first tray 11. The first camera module 12 also processes the images of the photoelectric element 20 to recognize a shape and position of the photoelectric element 20.

The base 13 defines a receiving recess 130 for receiving conductive glue 30.

The nozzle 14 is configured to vacuum-lift the photoelectric element 20. In detail, the nozzle 14 includes a holding surface 140 onto which the photoelectric element 20 is lifted. A hole (not shown) is defined in the holding surface 140 and extends to a vacuum pump (not shown) to enable the evacuation of air. To avoid the photoelectric element 20 being damaged by the nozzle 14, a buffer layer (not shown) is attached to the holding surface 140. In operation, when vacuum-lifted, only a part of the photoelectric element 20 is in contact with the holding surface 140.

The second camera module 15 is connected to the nozzle 14 and takes images of the parts of the photoelectric element 20 that are not obscured by the holding surface 140. In this embodiment, the second camera module 15 is housed in the nozzle 14.

The driver 16 supports and moves the nozzle 14 and is in communication with the first camera module 12. The driver 16 drives the nozzle 14 under supervision of the first camera module 12 to accurately position the holding surface 140 on the photoelectric element 20. The driver 16 also drives the nozzle 14 to dip the vacuum-lifted photoelectric element 20 into the conductive glue 30 such that the conductive glue 30 is applied to the bonding surface 200. The second camera module 15 takes images of the photoelectric element 20 to identify any tilting of the photoelectric element 20 during dipping. If tilting is identified, the dipping is deemed to fail and reworking is required. The driver 16 is in communication with the second camera module 15 and rejects the photoelectric element 20 if tilting is identified or otherwise passes on the photoelectric element 20 with supervision of the second camera module 15.

The second tray 17 supports the substrate 40. To increase efficiency, the second tray 17 can be configured to support a number of the substrates 40, which can be arrayed.

The third camera module 18 is positioned above the substrate 40 and takes images of the substrate 40 on the second tray 17. The third camera module 18 also takes images of the substrate 40 to recognize a shape and position of a substrate 40.

The driver 16 is also in communication with the third camera module 18 and drives the nozzle 14 under supervision of the third camera module 18 to accurately position the vacuum-lifted photoelectric element 20 on the substrate 40.

The first cameral module 12, the second camera module 15, and the third camera module 18 can be charge-coupled devices (CCD) or complementary metal-oxide semiconductor (CMOS) devices.

Under the supervision of the first camera module 12 and the third camera module 18, and with the monitoring by the second camera module 15, precision dipping and assembly of the photoelectric element 20 onto the substrate 40 is enhanced.

It will be understood that the above particular embodiments are shown and described by way of illustration only. The principles and the features of the present disclosure may be employed in various and numerous embodiments thereof without departing from the scope of the disclosure. The above-described embodiments illustrate the possible scope of the disclosure but do not restrict the scope of the disclosure.

What is claimed is:

1. A device, comprising:
a first tray for supporting a photoelectric element;
a first camera module positioned above the first tray and configured to take a plurality of images of the photoelectric element on the first tray, the first camera module being configured to process the images to recognize a shape and position of the photoelectric element;
a base defining a recess;
a conductive glue received in the recess;
a nozzle;
a driver connected to the nozzle and in communication with the first camera module, the driver being configured to drive the nozzle to suck a part of the photoelectric element under supervision of the first camera module, the driver being configured to drive the nozzle to dip the photoelectric element into the conductive glue;
a second camera module configured to take a plurality of images of a part of the photoelectric element that is not obstructed by the nozzle and process the images of the photoelectric element to identify any tilting of the photoelectric element during dipping, the driver being configured to reject the photoelectric element with supervision of the second camera module if tilting is identified or otherwise pass on the photoelectric element;
a second tray configured for supporting a substrate; and
a third camera module positioned above the second tray and configured to take images of the substrate on the second tray, the third camera module being configured to process the images to recognize a shape and position of the substrate; the driver being connected to the third camera module and further configured for driving the nozzle to move under supervision of the third camera module to accurately position the photoelectric element on the substrate.

2. The device of claim 1, wherein the first tray is configured to support a plurality of the photoelectric elements.

3. The device of claim 2, wherein the photoelectric elements are arrayed on the first tray.

4. The device of claim 1, wherein the second tray is configured to support a plurality of the substrates.

5. The device of claim 4, wherein the substrates are arrayed on the second tray.

6. The device of claim 1, wherein the first cameral module, the second camera module, and the third camera module are charge-coupled device based or complementary metal-oxide semiconductor based.
